(19) United States
(12) Patent Application Publication
(10) Pub. No.: US 2024/0304604 A1
(43) Pub. Date: Sep. 12, 2024

(54) DISPLAY DEVICE

(71) Applicant: Samsung Display Co., LTD., Yongin-si (KR)

(72) Inventors: Ki Chang EOM, Yongin-si (KR); Hui Won YANG, Yongin-si (KR); Jae Phil LEE, Yongin-si (KR)

(21) Appl. No.: 18/440,801

(22) Filed: Feb. 13, 2024

(30) Foreign Application Priority Data
Mar. 6, 2023 (KR) 10-2023-0029465

(51) Int. Cl. H01L 25/075

(52) U.S. Cl. CPC H01L 25/0753

(57) ABSTRACT

A display device includes a base layer on a plane defined by a first direction and a second direction different from the first direction, a front surface backplane layer on the base layer, and a light emitting element on the front surface backplane layer. The front surface backplane layer includes a first layer, a second layer on the first layer, and a third layer on the second layer. The first layer includes a first power line, a portion of the first power line extends in the first direction and another portion of the first power line extends in the second direction. The second layer includes a pixel circuit configured to drive the light emitting element. The third layer includes a second power line, a portion of the second power line extends in the first direction and another portion of the second power line extends in the second direction.

### CROSS-REFERENCE TO RELATED APPLICATIONS

This application claims priority to and the benefit of Korean Patent Application No. 10-2023-0029465 filed on Mar. 6, 2023, in the Korean Intellectual Property Office, the entire content of which is incorporated by reference herein.

### BACKGROUND

### 1. Field

The present disclosure relates to a display device.

### 2. Description of the Related Art

Recently, as interest in information display is increased, research and development on a display device is continuously conducted.

### SUMMARY

An aspect of the present disclosure is to provide a display device in which a short risk between electrodes may be reduced.

According to one or more embodiments of the present disclosure, a display device may include a base layer on a plane defined by a first direction and a second direction different from the first direction, a front surface backplane layer on the base layer, and a light emitting element on the front surface backplane layer. The front surface backplane layer may include a first layer, a second layer on the first layer, and a third layer on the second layer. The first layer may include a first power line, where at least a portion of the first power line extends in the first direction and at least another portion of the first power line extends in the second direction. The second layer may include a pixel circuit configured to drive the light emitting element. The third layer may include a second power line, where at least a portion of the second power line extends in the first direction and at least another portion of the second power line extends in the second direction. The first power line and the second power line may be physically separated by the second layer.

According to one or more embodiments, the second layer may include two or more insulating layers to electrically separate the first power line and the second power line.

According to one or more embodiments, the pixel circuit may include a transistor including a semiconductor layer. The first power line may overlap the semiconductor layer in a thickness direction of the base layer.

According to one or more embodiments, the first power line may include a light blocking material.

According to one or more embodiments, the second layer may further include a power connection line electrically connected to the first power line. The transistor may include a source electrode and a drain electrode. The power connection line may be on a same layer as the source electrode and the drain electrode.

According to one or more embodiments, the display device may further include pixels each including the light emitting element and being adjacent to each other. The pixel circuit may be in a pixel circuit area between the adjacent pixels. The pixel circuit area may overlap the first power line and the second power line in a thickness direction of the base layer.

According to one or more embodiments, each of the pixels may include a first sub-pixel, a second sub-pixel, and a third sub-pixel. The pixel circuit may include a first pixel circuit configured to drive the first sub-pixel, a second pixel circuit configured to drive the second sub-pixel, and a third pixel circuit configured to drive the third sub-pixel. The first pixel circuit, the second pixel circuit, and the third pixel circuit may be sequentially arranged along the first direction. The adjacent pixels may be spaced in the second direction.

According to one or more embodiments, the third layer may further include an anode electrode and a cathode electrode. The cathode electrode may be electrically connected to the second power line. The first power line may overlap the second power line, the anode electrode, and the cathode electrode in a thickness direction of the base layer.

According to one or more embodiments, the second layer may further include a bridge electrode. The bridge electrode may be electrically connected to a transistor of the pixel circuit. The anode electrode may be electrically connected to the bridge electrode through a contact portion. The first power line and the contact portion may overlap each other in a thickness direction of the base layer.

According to one or more embodiments, the cathode electrode and the second power line may be integrally formed.

According to one or more embodiments, the anode electrode and the cathode electrode may be spaced from each other in the first direction and may extend in the second direction.

According to one or more embodiments, the first power line may include an opening. The light emitting element may be located in an emission area. The opening and the emission area may overlap each other in a plan view.

According to one or more embodiments, the opening may overlap the anode electrode and the cathode electrode in a plan view.

According to one or more embodiments, the light emitting element may be a micro light-emitting diode.

According to one or more embodiments, the display device may further include a rear surface backplane layer on a rear surface of the base layer, and a driving circuit unit configured to supply an electrical signal to the light emitting element. The rear surface backplane layer may include a rear surface line electrically connected to the driving circuit unit.

According to one or more embodiments of the present disclosure, a display device may include a base layer on a plane defined by a first direction and a second direction different from the first direction, a front surface backplane layer on a first surface of the base layer, a rear surface backplane layer on a second surface of the base layer, a light-emitting-element layer on the front surface backplane layer and including an anode electrode, a cathode electrode, and a light emitting element electrically connected to the anode electrode and the cathode electrode. The front surface backplane layer may include a first layer, a second layer on the first layer, and a third layer on the second layer. The first layer may include a first power line, where at least a portion of the first power line extending in the first direction and at least another portion of the first power line extending in the second direction. The second layer may include a transistor configured to drive the light emitting element and a bridge electrode electrically connecting the transistor and the anode electrode. The third layer may include a second power line, where at least a portion of the second power line extending in the first direction and at least another portion of the second power line extending in the second direction. The bridge electrode and the first power line may overlap each other in a thickness direction of the base layer.

According to one or more embodiments of the present disclosure, a display device in which a short risk between electrodes may be reduced may be provided.

### BRIEF DESCRIPTION OF THE DRAWINGS

FIG. 1 is a plan view illustrating a display device according to one or more embodiments;

FIG. 2 is a diagram illustrating an example of a pixel of FIG. 1;

FIG. 3 is a schematic cross-sectional view illustrating a display device according to one or more embodiments;

FIG. 4 is a schematic plan view illustrating a display device according to one or more embodiments;

FIGS. 5 to 7 are schematic cross-sectional views illustrating a first backplane layer according to one or more embodiments;

FIGS. 8 to 10 are schematic plan views illustrating a first backplane layer according to one or more embodiments;

FIG. 11 is a schematic cross-sectional view taken along the line A-A′ of FIG. 10; and

FIG. 12 is a schematic cross-sectional view illustrating a display device according to one or more embodiments.

### DETAILED DESCRIPTION OF THE DRAWINGS

The present disclosure may be modified in various manners and have various forms. Therefore, specific embodiments will be illustrated in the drawings and will be described in detail in the specification. However, it should be understood that the present disclosure is not intended to be limited to the specific embodiments disclosed herein, and the present disclosure includes all modifications, equivalents, and substitutions within the spirit and technical scope of the embodiments of the present disclosure.

Terms of “first”, “second”, and the like may be used to describe various components, but the components should not be limited by the terms. The terms are used only for the purpose of distinguishing one component from another component. For example, without departing from the scope of the present disclosure, a first component may be referred to as a second component, and similarly, a second component may also be referred to as a first component. In the following description, the singular expressions include plural expressions unless the context clearly dictates otherwise.

It should be understood that in the present application, a term of “include”, “have”, or the like is used to specify that there is a feature, a number, a step, an operation, a component, a part, or a combination thereof described in the specification, but does not exclude a possibility of the presence or addition of one or more other features, numbers, steps, operations, components, parts, or combinations thereof in advance. In addition, a case where a portion of a layer, a layer, an area, a plate, or the like is referred to as being “on” another portion, it includes not only a case where the portion is “directly on” another portion, but also a case where there is further another portion between the portion and another portion. In addition, in the present specification, when a portion of a layer, a layer, an area, a plate, or the like is formed on another portion, a forming direction is not limited to an upper direction but includes forming the portion on a side surface or in a lower direction. On the contrary, when a portion of a layer, a layer, an area, a plate, or the like is formed “under” another portion, this includes not only a case where the portion is “directly beneath” another portion but also a case where there is further another portion between the portion and another portion.

The present disclosure relates to a display device. Hereinafter, a display device according to one or more embodiments is described with reference to the accompanying drawings.

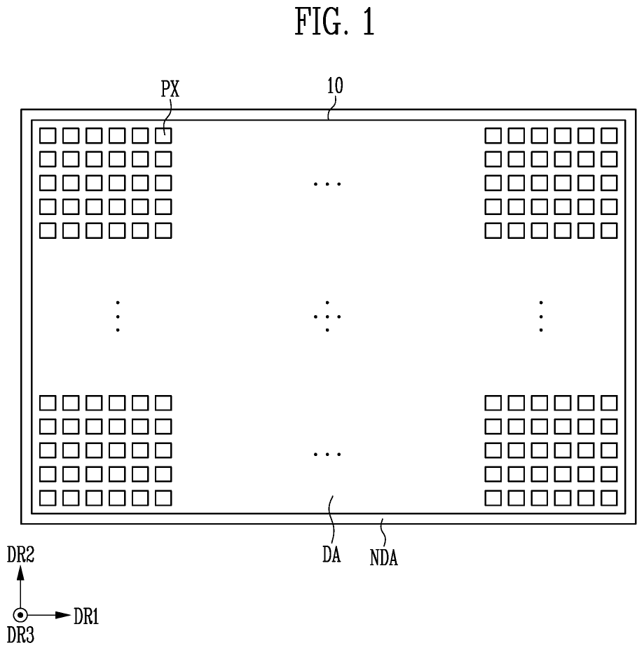

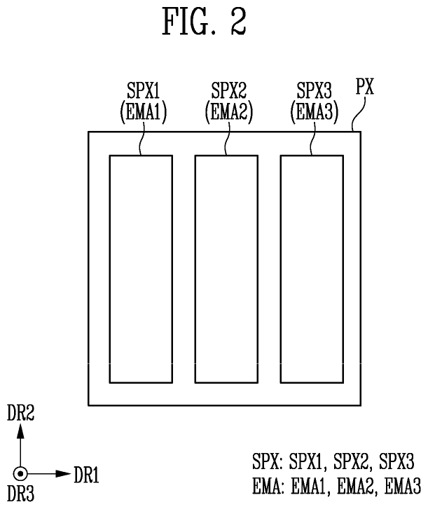

FIG. 1 is a plan view illustrating a display device according to one or more embodiments. FIG. 2 is a diagram illustrating an example of a pixel of FIG. 1.

Referring to FIG. 1, the display device 10 is configured to output light information. For example, the display device 10 may be a device for displaying a moving image or a still image, and may be applied to various devices. The display device 10 may be formed in a plane of a rectangular shape having a long side of a first direction DR1 and a short side of a second direction DR2 intersecting the first direction DR1. A corner where the long side of the first direction DR1 and the short side of the second direction DR2 meet may be formed to be rounded to have a suitable curvature (e.g., a predetermined curvature) or may be formed in a right angle. A planar shape of the display device 10 is not limited to a quadrangle, and may be formed in another polygon, circle, or ellipse. The display device 10 may be formed to be flat, but is not limited thereto. For example, the display device 10 may include a curved portion formed at left and right ends and having a constant curvature or a varying curvature. In addition, the display device 10 may be flexibly formed to be crooked, curved, bent, folded, and/or rolled.

The display device 10 may further include pixels PX, scan lines extending in the first direction DR1, and data lines extending in the second direction DR2 to display an image. The pixels PX may be arranged in a matrix shape along the first direction DR1 and the second direction DR2. For example, the pixels PX may be arranged along rows and columns of a matrix.

The display device 10 may include a display area DA and a non-display area NDA along an edge or periphery of the display area DA. According to one or more embodiments, the non-display area NDA may be disposed around the display area DA. The non-display area NDA may surround at least a portion of the display area DA.

The pixel PX may be disposed in the display area DA. The pixel PX may not be disposed in the non-display area NDA. Each of the pixels PX may include a plurality of sub-pixels SPX as shown in FIG. 2. FIG. 2 illustrates that each of the pixels PX includes three sub-pixels, that is, a first sub-pixel SPX1, a second sub-pixel SPX2, and a third sub-pixel SPX3, but the present disclosure is not limited thereto.

The first sub-pixel SPX1, the second sub-pixel SPX2, and the third sub-pixel SPX3 may be connected to any one data line from among the data lines and at least one scan line from among the scan lines.

Each of the first sub-pixel SPX1, the second sub-pixel SPX2, and the third sub-pixel SPX3 may have a planar shape of a rectangle, a square, or a rhombus. For example, as shown in FIG. 2, each of the first sub-pixel SPX1, the second sub-pixel SPX2, and the third sub-pixel SPX3 may have a planar shape of a rectangle having a short side of the first direction DR1 and a long side of the second direction DR2. Alternatively, according to one or more embodiments, each of the first sub-pixel SPX1, the second sub-pixel SPX2, and the third sub-pixel SPX3 may have a planar shape of a square or a rhombus including sides having a same length in the first direction DR1 and the second direction DR2.

As shown in FIG. 2, the first sub-pixel SPX1, the second sub-pixel SPX2, and the third sub-pixel SPX3 may be arranged along the first direction DR1. Alternatively, any one of the second sub-pixel SPX2 and the third sub-pixel SPX3 and the first sub-pixel SPX1 may be arranged along the first direction DR1, and the other one and the first sub-pixel SPX1 may also be arranged along the second direction DR2.

Alternatively, any one of the first sub-pixel SPX1 and the third sub-pixel SPX3 and the second sub-pixel SPX2 may be arranged along the first direction DR1, and the other one and the second sub-pixel SPX2 may be arranged along the second direction DR2.

Alternatively, any one of the first sub-pixel SPX1 and the second sub-pixel SPX2 and the third sub-pixel SPX3 may be arranged along the first direction DR1, and the other one and the third sub-pixel SPX3 may be arranged along the second direction DR2.

The first sub-pixel SPX1 may emit first light, the second sub-pixel SPX2 may emit second light, and the third sub-pixel SPX3 may emit third light. Here, the first light may be light of a red wavelength band, the second light may be light of a green wavelength band, and the third light may be light of a blue wavelength band. The red wavelength band may be a wavelength band of about 600 nm to 750 nm, the green wavelength band may be a wavelength band of about 480 nm to 560 nm, and the blue wavelength band may be a wavelength band of about 370 nm to 460 nm, but one or more embodiments of the present disclosure is not limited thereto.

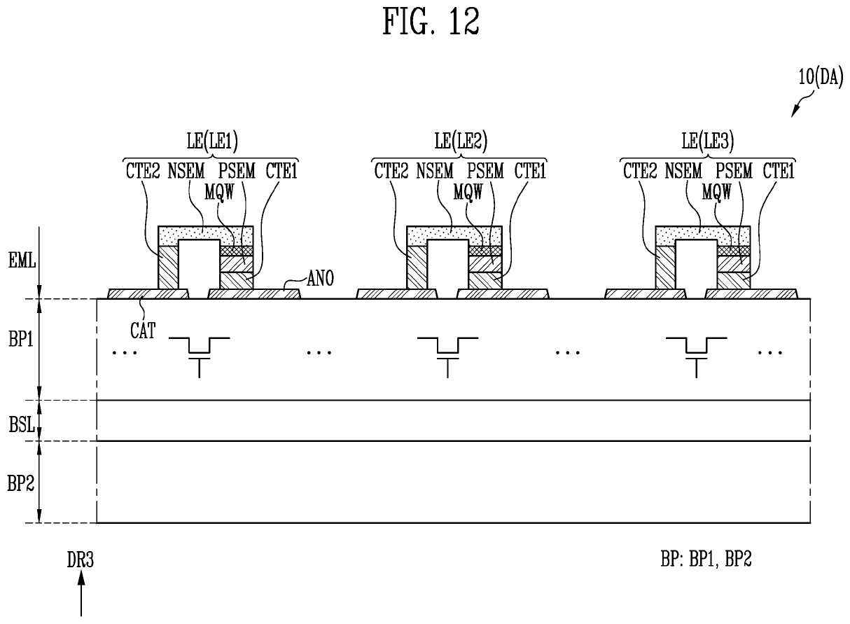

Each of the first sub-pixel SPX1, the second sub-pixel SPX2, and the third sub-pixel SPX3 may include an inorganic light emitting element including an inorganic semiconductor as a light emitting element LE (refer to FIG. 12) that emits light.

According to one or more embodiments, the light emitting element LE included in a sub-pixel SPX may be disposed in an emission area EMA. For example, a light emitting element LE included in the first sub-pixel SPX1 may be disposed in a first emission area EMA1. For example, the first emission area EMA1 may be an area where the light emitting element LE of the first sub-pixel SPX1 is disposed. A light emitting element LE included in the second sub-pixel SPX2 may be disposed in a second emission area EMA2. For example, the second emission area EMA2 may be an area where the light emitting element LE of the second sub-pixel SPX2 is disposed. A light emitting element LE included in the third sub-pixel SPX3 may be disposed in a third emission area EMA3. For example, the third emission area EMA3 may be an area where the light emitting element LE of the third sub-pixel SPX3 is disposed.

As shown in FIG. 2, the area of the first sub-pixel SPX1, the area of the second sub-pixel SPX2, and the area of the third sub-pixel SPX3 may be substantially a same, but the present disclosure is not limited thereto. At least one of the area of the first sub-pixel SPX1, the area of the second sub-pixel SPX2, and the area of the third sub-pixel SPX3 may be different from another area. Alternatively, any two of the area of the first sub-pixel SPX1, the area of the second sub-pixel SPX2, and the area of the third sub-pixel SPX3 may be substantially the same and the other one may be different from the two areas. Alternatively, the area of the first sub-pixel SPX1, the area of the second sub-pixel SPX2, and the area of the third sub-pixel SPX3 may be different from each other.

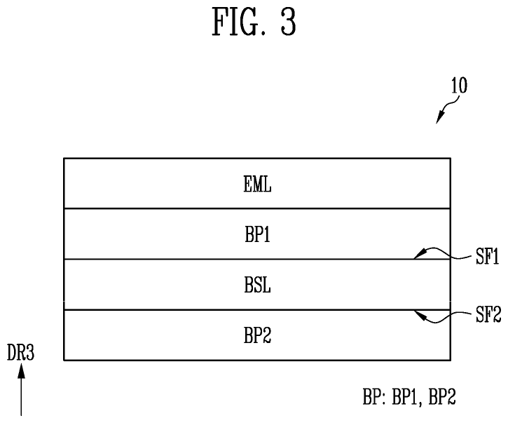

FIG. 3 is a schematic cross-sectional view illustrating a display device according to one or more embodiments.

Referring to FIG. 3, the display device 10 according to one or more embodiments may include a base layer BSL, a backplane layer BP, and a light-emitting-element layer EML.

The base layer BSL may be a base substrate or a base member for supporting the display device 10. The base layer BSL may be a rigid substrate of a glass material. Alternatively, the base layer BSL may be a flexible substrate of which bending, folding, rolling, or the like is possible. In this case, the substrate may include an insulating material such as a polymer resin such as polyimide. However, the present disclosure is not necessarily limited thereto.

The base layer BSL may be disposed (or formed) on a plane defined by the first direction DR1 and the second direction DR2. The plane may be parallel to the first direction DR1 and may be parallel to the second direction DR2.

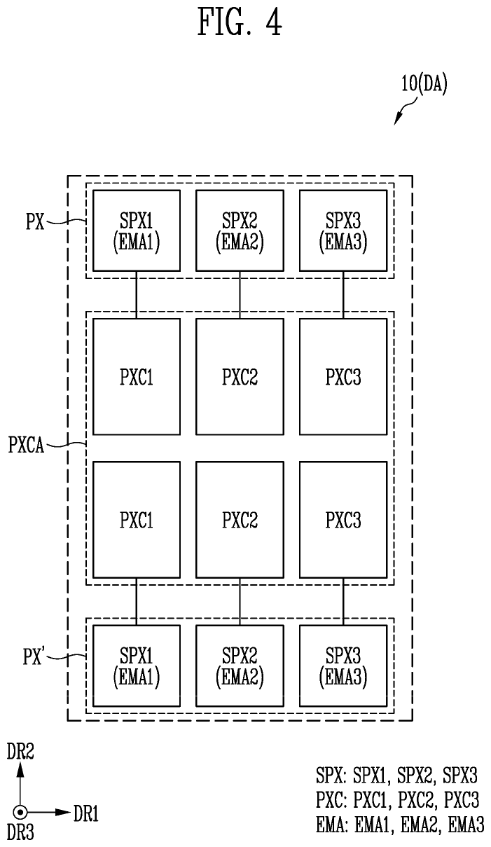

The backplane layer BP may include metal layers for forming pixel circuits PXC (refer to FIG. 4) and lines, and one or more insulating layers disposed between the metal layers.

According to one or more embodiments, the backplane layer BP may include a first backplane layer BP1 and a second backplane layer BP2. The first backplane layer BP1 and the second backplane layer BP2 may be disposed on both surfaces of opposite sides of the base layer BSL, respectively.

According to one or more embodiments, the first backplane layer BP1 may be a pixel circuit layer. The second backplane layer BP2 may be a rear surface line layer. The first backplane layer BP1 may be a front surface backplane layer. The second backplane layer BP2 may be a rear surface backplane layer.

The first backplane layer BP1 may be a layer including a pixel circuit PXC for driving the pixel PX. The first backplane layer BP1 may be disposed on a first surface (for example, a front surface) SF1 of the base layer BSL. According to one or more embodiments, the first backplane layer BP1 may be disposed between the base layer BSL and the light-emitting-element layer EML.

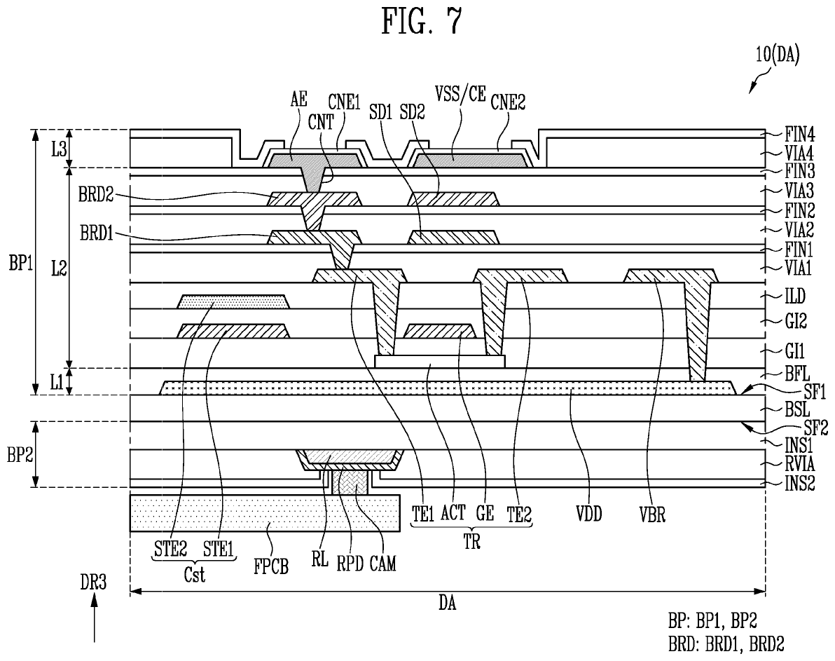

The second backplane layer BP2 may be a layer including rear surface lines RL (refer to FIG. 7) electrically connected to a driving circuit unit FPCB (refer to FIG. 7) disposed on a second surface SF2 of the base layer BSL. The second backplane layer BP2 may be disposed on a second surface (for example, a rear surface) SF2 of the base layer BSL.

The second surface SF2 may be a surface opposite to the first surface SF1.

The rear surface lines RL formed on the second backplane layer BP2 may be electrically connected to the driving circuit unit FPCB (e.g., see FIG. 7). The rear surface lines RL formed on the second backplane layer BP2 may provide an electrical signal provided from the driving circuit unit FPCB to the front surface lines of the first backplane layer BP1 through side surface lines.

The light-emitting-element layer EML may be disposed on the first backplane layer BP1. The light-emitting-element layer EML may include the light emitting element LE configured to emit light based on a signal provided from the pixel circuit PXC of the first backplane layer BP1.

Next, with reference to FIGS. 4 to 11, the first backplane layer BP1 according to one or more embodiments is described in more detail.

FIG. 4 is a schematic plan view illustrating a display device according to one or more embodiments. FIG. 4 shows a planar structure in which the sub-pixels SPX and the pixel circuit PXC according to one or more embodiments are disposed.

Referring to FIG. 4, the sub-pixel SPX may include the first sub-pixel SPX1, the second sub-pixel SPX2, and the third sub-pixel SPX3. The pixel circuit PXC may include a first pixel circuit PXC1, a second pixel circuit PXC2, and a third pixel circuit PXC3.

According to one or more embodiments, the first pixel circuit PXC1, the second pixel circuit PXC2, and the third pixel circuit PXC3 may be sequentially disposed on the first direction DR1.

The sub-pixel SPX and the pixel circuit PXC may be electrically connected to each other. For example, the first sub-pixel SPX1 may be electrically connected to the first pixel circuit PXC1. The second sub-pixel SPX2 may be electrically connected to the second pixel circuit PXC2. The third sub-pixel SPX3 may be electrically connected to the third pixel circuit PXC3.

The pixel circuit PXC may be disposed between adjacent pixels PX and PX′. For example, a pixel circuit area PXCA in which the pixel circuit PXC is disposed may overlap the pixels PX and PX′ adjacent to each other on the second direction DR2. The pixel circuit area PXCA may overlap a first power line VDD in a thickness direction (i.e., DR3) of the base layer BSL. The pixel circuit area PXCA may overlap a second power line VSS in a thickness direction (i.e., DR3) of the base layer BSL. According to one or more embodiments, the pixel circuit area PXCA may entirely overlap the first power line VDD and the second power line VSS in a thickness direction (i.e., DR3) of the base layer BSL.

According to one or more embodiments, the pixel circuit PXC may include a circuit element including a transistor TR and may supply a driving signal to the sub-pixel SPX. Accordingly, the light emitting element LE of each sub-pixel SPX may emit light based on the driving signal.

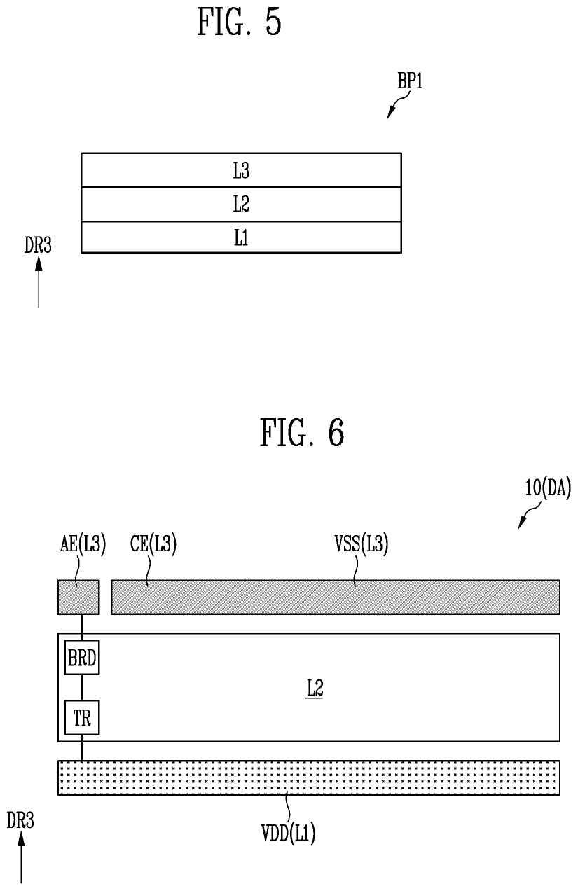

FIGS. 5 to 7 are schematic cross-sectional views illustrating a first backplane layer according to one or more embodiments. FIG. 5 is a schematic cross-sectional view illustrating one or more layers forming the first backplane layer BP1. FIG. 6 is a schematic cross-sectional view illustrating a connection relationship between one or more layers forming the first backplane layer BP1. FIG. 7 is a schematic cross-sectional view illustrating one or more layers forming the first backplane layer BP1 in detail.

Referring to FIGS. 5 to 7, the first backplane layer BP1 may include three or more layers. For example, the first backplane layer BP1 may include a first layer L1, a second layer L2, and a third layer L3.

The first layer L1 may be a layer the most adjacent to the base layer BSL from among the first to third layers L1, L2, and L3. The first layer L1 may be disposed between the base layer BSL and the second layer L2.

The first layer L1 may include the first power line VDD. For example, at least a portion of a conductive layer forming the first layer L1 may form the first power line VDD.

The first power line VDD may supply first power to the sub-pixel SPX (or the light emitting element LE). For example, the first power may form a high-potential pixel potential.

The first power line VDD may overlap an anode electrode AE, a cathode electrode CE, and the second power line VSS in a thickness direction (i.e., DR3) of the base layer BSL. The first power line VDD may overlap the transistor TR and the bridge electrode BRD in a thickness direction (i.e., DR3) of the base layer BSL.

The second layer L2 may be disposed on the first layer L1. The second layer L2 may be disposed between the first layer L1 and the third layer L3.

The second layer L2 may include the transistor TR forming the pixel circuit PXC and the bridge electrode BRD electrically connecting the transistor TR and the anode electrode AE. According to one or more embodiments, the second layer L2 may further include one or more lines for forming the pixel circuit PXC.

The transistor TR may be electrically connected to the first power line VDD. The transistor TR may be electrically connected to the anode electrode AE of the third layer L3 through the bridge electrode BRD. Accordingly, the first power line VDD may supply power to the anode electrode AE through the transistor TR and the bridge electrode BRD.

According to one or more embodiments, the transistor TR and the bridge electrode BRD may be selectively disposed on a partial area of the second layer L2. For example, lines forming a conductive structure of the second layer L2 may not be disposed in at least some areas in the display area DA.

The third layer L3 may be disposed on the second layer L2. The third layer L3 may be disposed between the second layer L2 and the light-emitting-element layer EML.

The third layer L3 may include the anode electrode AE, the cathode electrode CE, and the second power line VSS. For example, at least a portion of a conductive layer forming the third layer L3 may form the anode electrode AE, the cathode electrode CE, and the second power line VSS.

The second power line VSS may supply second power to the sub-pixel SPX (or the light emitting element LE). For example, the second power may form a low-potential pixel potential. The second power line VSS may receive an electrical signal through another power connection line formed in the second layer L2.

According to one or more embodiments, the second power line VSS may supply the second power to the sub-pixel SPX (or the light emitting element LE), and the first power line VDD may supply the first power to the sub-pixel SPX (or the light emitting element LE). The second power may have a potential lower than that of the first power. Accordingly, one potential difference may be formed in an electrical path before and after the sub-pixel SPX (or the light emitting element LE).

The first power line VDD and the second power line VSS may extend on a plane in the display area DA. For example, the first power line VDD and the second power line VSS may be widely disposed in a generally wide area. The first power line VDD and the second power line VSS may have a plate shape extending on one plane. For example, the first power line VDD and the second power line VSS may have a substantially flat structure, at least a portion of the first power line VDD may extend in the first direction DR1, and at least another portion of the first power line VDD may extend in the second direction DR2. At least a portion of the second power line VSS may extend in the first direction DR1, and at least another of the second power line VSS may extend in the second direction DR2.

In the present disclosure, the “plate shape” may mean a shape having a relatively less thickness and expanded (or extended) in a plane direction (for example, an area direction of the base layer BSL, or a plane direction on the first direction DR1 and the second direction DR2). The plane direction may be parallel to a plane defined by the first direction DR1 and the second direction DR2 on which the base layer BSL is disposed.

According to one or more embodiments, the first power line VDD may generally cover the base layer BSL. The second power line VSS may generally cover the base layer BSL. For example, the first power line VDD may cover 90% or more of the area of the base layer BSL. The second power line VSS may cover 90% or more of the area of the base layer BSL. However, the present disclosure is not necessarily limited to the above-described numerical range.

As the first power line VDD and the second power line VSS has a shape expanded (or extended) on a plane, a resistance of the first power line VDD and the second power line VSS may be reduced, and a resistance deviation between areas of the display area DA may be reduced. Accordingly, a voltage drop risk in the display device 10 may be prevented.

The first power line VDD and the second power line VSS may not be directly adjacent to each other. For example, the first power line VDD and the second power line VSS may be generally disposed in a wide area, and the second layer L2 may be disposed between the first power line VDD and the second power line VSS. Accordingly, a short circuit risk between the first power line VDD and the second power line VSS may be reduced.

Experimentally, when the first power line VDD and the second power line VSS are spaced from each other with a single layer interposed therebetween, a concern that the first power line VDD and the second power line VSS are connected to each other and thus a short circuit defect occurs during a manufacturing process exists. However, according to one or more embodiments, the first power line VDD and the second power line VSS may be spaced by the second layer L2 including two or more insulating layers, and thus the short circuit risk between the first power line VDD and the second power line VSS may be reduced even in a case where the first power line VDD and the second power line VSS are formed in a generally wide area.

In addition, a short circuit defect may be prevented because the first power line VDD is disposed in the first layer L1, the first power line VDD may overlap at least a portion of the transistor TR, and thus light that may affect the transistor TR may be blocked. Details regarding this are described later.

The second power line VSS and the cathode electrode CE may be electrically connected. For example, the second power line VSS and the cathode electrode CE may be integrally formed with each other. The second power line VSS may supply power to the cathode electrode CE.

The second power line VSS and the cathode electrode CE may be spaced from the anode electrode AE. For example, the anode electrode AE, the cathode electrode CE, and the second power line VSS may be formed in a same process, may be disposed on a same layer, and may include a same material. The cathode electrode CE and the second power line VSS may not contact the anode electrode AE. For example, the cathode electrode CE and the anode electrode AE may be spaced from each other with one area interposed therebetween.

FIG. 7 specifically shows one of examples of the first backplane layer BP1 according to one or more embodiments. However, the present disclosure is not necessarily limited thereto. For example, the number of conductive layers and insulating layers forming the second layer L2 may be different from that of FIG. 7.

Referring to FIG. 7, the first layer L1 may include the first power line VDD and a buffer layer BFL. The second layer L2 may include the transistor TR, a storage capacitor Cst, the bridge electrode BRD, a power connection line VBR, a first data electrode SD1, a second data electrode SD2, and a plurality of insulating layers GI1, GI2, ILD, VIA1, VIA2, VIA3, FIN1, FIN2, and FIN3. The third layer L3 may include the anode electrode AE, the cathode electrode CE, a first connection electrode CNE1, a second connection electrode CNE2, and a plurality of insulating layers VIA4 and FIN4.

The base layer BSL may form a base on which the backplane layer BP is disposed.

The first power line VDD may include a conductive material and may be covered by the buffer layer BFL. The first power line VDD may include one or more materials selected from a group of copper (Cu), molybdenum (Mo), tungsten (W), aluminum neodymium (AlNd), titanium (Ti), aluminum (Al), silver (Ag), and an alloy thereof. However, the present disclosure is not limited thereto.

The first power line VDD may overlap the transistor TR in a thickness direction (i.e., DR3) of the base layer BSL. For example, the first power line VDD may overlap a semiconductor layer ACT of the transistor TR in a thickness direction (i.e., DR3) of the base layer BSL.

According to one or more embodiments, after the first backplane layer BP1 is formed on the first surface SF1 of the base layer BSL, the second backplane layer BP2 may be formed on the second surface SF2 of the base layer BSL. During a process of forming the second backplane layer BP2, UV light may be generated. When the UV light is applied to the semiconductor layer ACT, a risk that a threshold voltage of the transistor TR may be shifted may occur.

However, according to one or more embodiments, because the first power line VDD may include a light blocking material having conductivity and may cover at least a portion of the transistor TR in the third direction DR3, a concern that light is applied to the transistor TR and circuit performance is damaged may be reduced. Here, the light blocking material may mean a material capable of blocking at least a portion of light of a UV wavelength band, and is not limited to a specific example.

The buffer layer BFL may be disposed on the base layer BSL and the first power line VDD. The buffer layer BFL may prevent diffusion of an impurity into a circuit element (for example, the transistor TR). The buffer layer BFL may include an inorganic material.

For example, the buffer layer BFL may include one or more materials selected from a group of silicon nitride (SiNx), silicon oxide (SiOx), silicon oxynitride (SiOxNy), and aluminum oxide (AlxOy). However, the present disclosure is not necessarily limited to the above-described example.

The transistor TR may include the semiconductor layer ACT, a first transistor electrode TE1, a second transistor electrode TE2, and a gate electrode GE. According to one or more embodiments, the transistor TR may include a driving transistor. According to one or more embodiments, the transistor TR may further include a switching transistor.

The semiconductor layer ACT, the first transistor electrode TE1, and the second transistor electrode TE2 may be disposed on the buffer layer BFL.

The semiconductor layer ACT may be an area overlapping the gate electrode GE in the third direction DR3 and may include a channel area, a source area, and a drain area of the transistor TR. The source area may be a partial area of the semiconductor layer ACT, and may be electrically connected to the first transistor electrode TE1 through a contact hole penetrating through the insulating layers GI1, GI2, and ILD. The drain area may be a partial area of the semiconductor layer ACT, and may be electrically connected to the second transistor electrode TE2 through a contact hole penetrating through the insulating layers GI1, GI2, and ILD. The first transistor electrode TE1 may be a source electrode and the second transistor electrode TE2 may be a drain electrode, but the present disclosure is not limited thereto.

The semiconductor layer ACT may include one or more materials selected from a group of polysilicon, low temperature polycrystalline silicon (LTPS), amorphous silicon, and oxide semiconductor. For example, the source area and the drain area may be formed of a semiconductor layer doped with an impurity, and the channel area may be formed of a semiconductor layer that is not doped with an impurity. As the impurity, for example, an n-type impurity may be used, but the present disclosure is not limited thereto.

The gate electrode GE may include a conductive material and may be disposed on a first gate insulating layer GI1. The gate electrode GE may overlap the semiconductor layer ACT in a thickness direction (i.e., DR3) of the base layer BSL. For example, the gate electrode GE may include one or more materials selected from a group of copper (Cu), molybdenum (Mo), tungsten (W), aluminum neodymium (AlNd), titanium (Ti), aluminum (Al), silver (Ag), and an alloy thereof. However, the present disclosure is not limited thereto.

The first gate insulating layer GI1 may be disposed on the buffer layer BFL and the semiconductor layer ACT. The first gate insulating layer GI1 may include an inorganic material. For example, the first gate insulating layer GI1 may include one or more materials selected from a group of silicon nitride (SiNx), silicon oxide (SiOx), silicon oxynitride (SiOxNy), and aluminum oxide (AlxOy). However, the present disclosure is not necessarily limited to the above-described example.

A first storage electrode STE1 may be disposed on the first gate insulating layer GI1.

A second gate insulating layer GI2 may be disposed on the first gate insulating layer GI1, the gate electrode GE, and the first storage electrode STE1. The second gate insulating layer GI2 may include an inorganic material. For example, the second gate insulating layer GI2 may include one or more materials selected from a group of silicon nitride (SiNx), silicon oxide (SiOx), silicon oxynitride (SiOxNy), and aluminum oxide (AlxOy). However, the present disclosure is not necessarily limited to the above-described example.

The second storage electrode STE2 may be disposed on the second gate insulating layer GI2. The second storage electrode STE2 may overlap the first storage electrode STE1 in the third direction DR3 to form the storage capacitor Cst together with the first storage electrode STE1.

An interlayer insulating layer ILD may be disposed on the second gate insulating layer GI2 and the second storage electrode STE2. The interlayer insulating layer ILD may include an inorganic material. For example, the interlayer insulating layer ILD may include one or more materials selected from a group of silicon nitride (SiNx), silicon oxide (SiOx), silicon oxynitride (SiOxNy), and aluminum oxide (AlxOy). However, the present disclosure is not necessarily limited to the above-described example.

The first transistor electrode TE1 and the second transistor electrode TE2 may be disposed on the interlayer insulating layer ILD. The first transistor electrode TE1 may be electrically connected to the source area of the semiconductor layer ACT through a contact member passing through the interlayer insulating layer ILD, the second gate insulating layer GI2, and the first gate insulating layer GI1, and the second transistor electrode TE2 may be connected to the drain area of the semiconductor layer ACT through a contact member passing through the interlayer insulating layer ILD, the second gate insulating layer GI2, and the first gate insulating layer GI1. The first transistor electrode TE1 may be electrically connected to a first bridge electrode BRD1 to be described later.

The power connection line VBR may be disposed on the interlayer insulating layer ILD. The power connection line VBR may be electrically connected to the first power line VDD through a contact member passing through the buffer layer BFL, the interlayer insulating layer ILD, the second gate insulating layer GI2, and the first gate insulating layer GI1.

The power connection line VBR may be formed in a same process and may include a same material as the first transistor electrode TE1 and the second transistor electrode TE2. The power connection line VBR may be electrically connected to the second transistor electrode TE2. Accordingly, the power supplied by the first power line VDD may be applied to the second transistor electrode TE2 through the power connection line VBR.

The power connection line VBR may not have a shape that extends on a plane. The power connection line VBR may not have a plate shape.

The power connection line VBR may not overlap the anode electrode AE and the cathode electrode CE in a thickness direction (i.e., DR3) of the base layer BSL. According to one or more embodiments, the power connection line VBR may overlap the first power line VDD in a thickness direction (i.e., DR3) of the base layer BSL. As the power connection line VBR does not overlap the anode electrode AE and the cathode electrode CE in a thickness direction (i.e., DR3) of the base layer BSL, a short circuit risk between the electrodes may be further prevented.

According to one or more embodiments, the power connection line VBR may include one or more materials selected from a group of copper (Cu), molybdenum (Mo), tungsten (W), aluminum neodymium (AlNd), titanium (Ti), aluminum (Al), silver (Ag), and an alloy thereof. However, the present disclosure is not necessarily limited to the above-described example.

A first via layer VIA1 may be disposed on the first transistor electrode TE1, the second transistor electrode TE2, the power connection line VBR, and the interlayer insulating layer ILD. The first via layer VIA1 may include at least one organic insulating layer. The first via layer VIA1 may include one or more selected from among acrylic resin, epoxy resin, phenol resin, polyamide resin, and/or polyimide resin. However, the present disclosure is not limited thereto.

A first front surface insulating layer FIN1 may be disposed on the first via layer VIA1. The first front surface insulating layer FIN1 may include an inorganic material. For example, the first front surface insulating layer FIN1 may include one or more materials selected from group of silicon nitride (SiNx), silicon oxide (SiOx), silicon oxynitride (SiOxNy), and aluminum oxide (AlxOy). However, the present disclosure is not necessarily limited to the above-described example.

The bridge electrode BRD may include a first bridge electrode BRD1 and a second bridge electrode BRD2.

The first bridge electrode BRD1 and a first data electrode SD1 may be disposed on the first front surface insulating layer FIN1. The first bridge electrode BRD1 may be electrically connected to the first transistor electrode TE1 through a contact member penetrating through the first front surface insulating layer FIN1 and the first via layer VIA1. For example, the first data electrode SD1 may correspond to a data line, a driving voltage line, a driving low voltage line, and the like. The first bridge electrode BRD1 and the first data electrode SD1 may include one or more materials selected from a group of copper (Cu), molybdenum (Mo), tungsten (W), aluminum neodymium (AlNd), titanium (Ti), aluminum (Al), silver (Ag), and an alloy thereof. However, the present disclosure is not necessarily limited to the above-described example.

A second via layer VIA2 may be disposed on the first front surface insulating layer FIN1, the first bridge electrode BRD1, and the first data electrode SD1. The second via layer VIA2 may include at least one organic insulating layer. The second via layer VIA2 may include one or more materials selected from a group of acrylic resin, epoxy resin, phenol resin, polyamide resin, and polyimide resin. However, the present disclosure is not limited thereto.

A second front surface insulating layer FIN2 may be disposed on the second via layer VIA2. The second front surface insulating layer FIN2 may include an inorganic material. For example, the second front surface insulating layer FIN2 may include one or more materials selected from a group of silicon nitride (SiNx), silicon oxide (SiOx), silicon oxynitride (SiOxNy), and aluminum oxide (AlxOy). However, the present disclosure is not necessarily limited to the above-described example.

The second bridge electrode BRD2 and the second data electrode SD2 may be disposed on the second front surface insulating layer FIN2. The second bridge electrode BRD2 may be electrically connected to the first bridge electrode BRD1 through a contact member penetrating through the second front surface insulating layer FIN2 and the second via layer VIA2. For example, the second data electrode SD2 may correspond to a data line, a driving voltage line, a driving low voltage line, and the like. The second bridge electrode BRD2 and the second data electrode SD2 may include one or more materials selected from a group of copper (Cu), molybdenum (Mo), tungsten (W), aluminum neodymium (AlNd), titanium (Ti), aluminum (Al), silver (Ag), and an alloy thereof. However, the present disclosure is not necessarily limited to the above-described example.

A third via layer VIA3 may be disposed on the second front surface insulating layer FIN2, the second bridge electrode BRD2, and the second data electrode SD2. The third via layer VIA3 may include at least one organic insulating layer. The third via layer VIA3 may include one or more materials selected from a group of acrylic resin, epoxy resin, phenol resin, polyamide resin, and polyimide resin. However, the present disclosure is not limited thereto.

A third front surface insulating layer FIN3 may be disposed on the third via layer VIA3. The third front surface insulating layer FIN3 may include an inorganic material. For example, the third front surface insulating layer FIN3 may include one or more materials selected from a group of silicon nitride (SiNx), silicon oxide (SiOx), silicon oxynitride (SiOxNy), and aluminum oxide (AlxOy). However, the present disclosure is not necessarily limited to the above-described example.

The anode electrode AE may be disposed on the third front surface insulating layer FIN3. The anode electrode AE may be electrically connected to an upper surface of the second bridge electrode BRD2 exposed by the third front surface insulating layer FIN3 and the third via layer VIA3 through a contact portion CNT, and may be electrically connected to the first transistor electrode TE1 through the second bridge electrode BRD2 and the first bridge electrode BRD1. The anode electrode AE may be electrically connected to a first electrode ANO (refer to FIG. 12) electrically connected to the light emitting element LE.

The cathode electrode CE may be disposed on the third front surface insulating layer FIN3. The cathode electrode CE may be electrically connected to a second electrode CAT (refer to FIG. 12) electrically connected to the light emitting element LE.

The cathode electrode CE and the anode electrode AE may include one or more materials selected from a group of copper (Cu), molybdenum (Mo), tungsten (W), aluminum neodymium (AlNd), titanium (Ti), aluminum (Al), silver (Ag), and an alloy thereof. However, the present disclosure is not necessarily limited to the above-described example.

A first connection electrode CNE1 may be disposed on the anode electrode AE to cover the anode electrode AE. A second connection electrode CNE2 may be disposed on the cathode electrode CE to cover the cathode electrode CE. The first connection electrode CNE1 and the second connection electrode CNE2 may include a transparent conductive oxide. For example, the first connection electrode CNE1 and the second connection electrode CNE2 may include one or more selected from among indium tin oxide (ITO), indium zinc oxide (IZO), zinc oxide (ZnO), indium gallium zinc oxide (IGZO), indium tin zinc oxide (ITZO), and/or the like.

A fourth via layer VIA4 may be disposed on a portion of the third front surface insulating layer FIN3. The fourth via layer VIA4 may expose an upper surface of the first connection electrode CNE1 and an upper surface of the second connection electrode CNE2. The fourth via layer VIA4 may include one or more materials selected from a group of acrylic resin, epoxy resin, phenol resin, polyamide resin, and polyimide resin. However, the present disclosure is not limited thereto.

A fourth front surface insulating layer FIN4 may be disposed on the fourth via layer VIA4, the first connection electrode CNE1, and the second connection electrode CNE2. The fourth front surface insulating layer FIN4 may be disposed to expose a portion of the upper surface of the first connection electrode CNE1 and a portion of the upper surface of the second connection electrode CNE2. An exposed portion of the upper surface of the first connection electrode CNE1 may be electrically connected to a pixel electrode PXE, and an exposed portion of the upper surface of the second connection electrode CNE2 may be electrically connected to the cathode electrode CE.

The second backplane layer BP2 may include a rear surface line RL, a rear surface pad electrode RPD, a first insulating layer INS1, a second insulating layer INS2, and a rear surface via layer RVIA, which are disposed on the second surface SF2 of the base layer BSL.

The first insulating layer INS1 may be disposed on the second surface SF2 of the base layer BSL. The first insulating layer INS1 may include an inorganic material.

The rear surface line RL may be disposed on the first insulating layer INS1. The rear surface line RL may include one or more materials selected from a group of copper (Cu), molybdenum (Mo), tungsten (W), aluminum neodymium (AlNd), titanium (Ti), aluminum (Al), silver (Ag), and an alloy thereof. However, the present disclosure is not necessarily limited to the above-described example.

The rear surface pad electrode RPD may be disposed on the rear surface line RL. The rear surface pad electrode RPD may be disposed on the rear surface line RL and the first insulating layer INS1 to cover the rear surface line RL.

The second insulating layer INS2 may be disposed on the rear surface pad electrode RPD. The second insulating layer INS2 may cover the rear surface pad electrode RPD to expose at least a portion of an upper surface of the rear surface pad electrode RPD, and may cover the first insulating layer INS1. A conductive adhesive member CAM may be disposed on the upper surface of the rear surface pad electrode RPD exposed by the second insulating layer INS2. The rear surface pad electrode RPD may be electrically connected to the driving circuit unit FPCB through the conductive adhesive member CAM.

The conductive adhesive member CAM may be an anisotropic conductive film or an anisotropic conductive paste. The driving circuit unit FPCB may include a flexible circuit board. The driving circuit unit FPCB may include a source driving circuit for supplying data voltages to data lines.

The second insulating layer INS2 may include an inorganic material. For example, the second insulating layer INS2 may include one or more materials selected from a group of silicon nitride (SiNx), silicon oxide (SiOx), silicon oxynitride (SiOxNy), and aluminum oxide (AlxOy). However, the present disclosure is not necessarily limited to the above-described example.

According to one or more embodiments, the rear surface via layer RVIA may be disposed between the first insulating layer INS1 and the second insulating layer INS2. The rear surface via layer RVIA may be disposed on the first insulating layer INS1 and may be disposed to cover the rear surface line RL and the rear surface pad electrode RPD. The rear surface via layer RVIA may be disposed to cover the rear surface pad electrode RPD, to expose at least a portion of the upper surface of the rear surface pad electrode RPD. The rear surface via layer RVIA may include one or more materials selected from a group of acrylic resin, epoxy resin, phenol resin, polyamide resin, and polyimide resin. However, the present disclosure is not limited thereto.

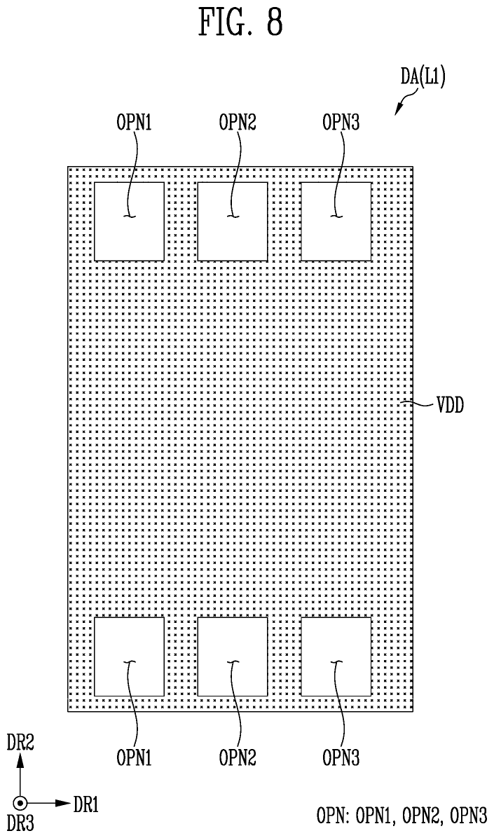

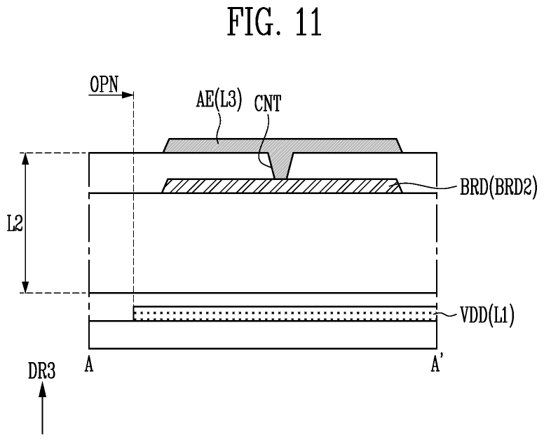

FIGS. 8 to 10 are schematic plan views illustrating a first backplane layer according to one or more embodiments. FIG. 11 is a schematic cross-sectional view taken along the line A-A′ of FIG. 10.

Referring to FIGS. 8 to 10, in the display area DA, the first layer L1 and the third layer L3 may overlap in a thickness direction (i.e., DR3) of the base layer BSL. For example, as described above, the first power line VDD and the second power line VSS may have an expanded shape on a plane and may overlap each other in a generally large area when in a thickness direction (i.e., DR3) of the base layer BSL.

As described above, because the first power line VDD and the second power line VSS are expanded in a generally large area, the first power line VDD and the second power line VSS may have a low resistance. Because the second layer L2 including two or more layers is interposed between the first power line VDD and the second power line VSS (e.g., FIGS. 6-7), a short defect may be prevented, while the first power line VDD and the second power line VSS form an overlapping area a thickness direction (i.e., DR3) of the base layer BSL.

As shown in FIG. 8, the first power line VDD may include an opening OPN. For example, an opening OPN may be formed in the first power line VDD. The opening OPN may refer to an area where the first power line VDD is not disposed. A position of the opening OPN may correspond to a position of the emission area EMA.

For example, the opening OPN may include a first opening OPN1, a second opening OPN2, and a third opening OPN3. The first opening OPN1 may overlap a first emission area EMA1 in a plan view. The second opening OPN2 may overlap a second emission area EMA2 in a plan view. The third opening OPN3 may overlap a third emission area EMA3 in a plan view.

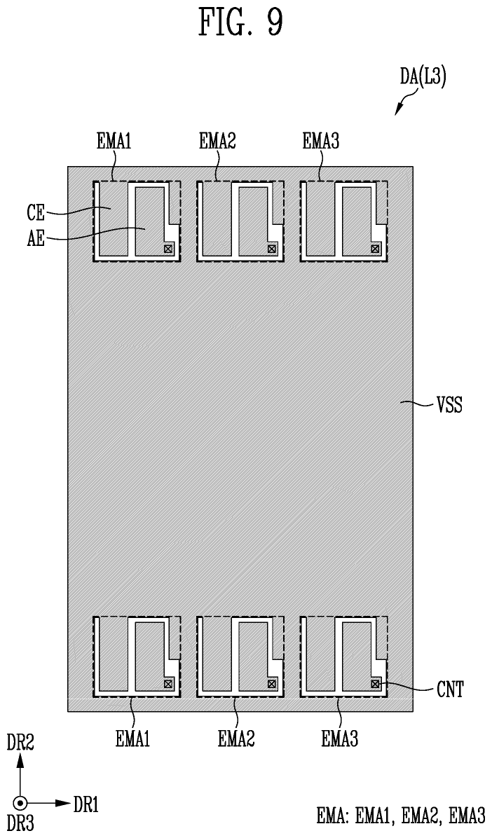

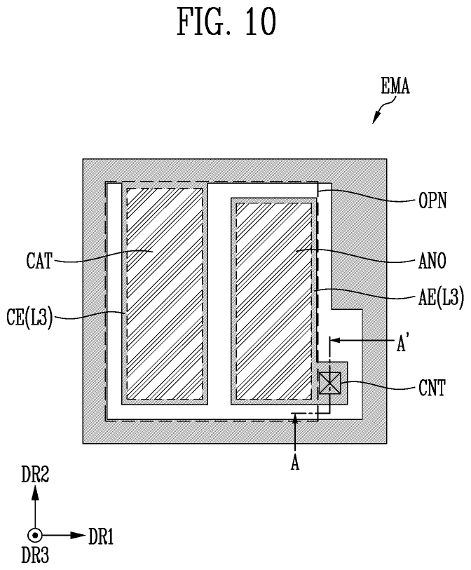

According to one or more embodiments, the opening OPN may overlap the anode electrode AE and the cathode electrode CE in a plan view (e.g., FIG. 9). According to one or more embodiments, the emission area EMA may be a portion of the third layer L3 in a plan view, and may overlap the anode electrode AE and the cathode electrode CE. For example, each of the anode electrode AE and the cathode electrode CE may extend in the second direction DR2 in the emission area EMA and may be spaced from each other in the first direction DR1.

The anode electrode AE included in the third layer L3 may be electrically connected to the pixel circuit PXC included in the second layer L2 through the contact portion CNT. For example, the anode electrode AE may be electrically connected to the second bridge electrode BRD2 through the contact portion CNT (e.g., FIG. 7).

According to one or more embodiments, the contact portion CNT may overlap the first power line VDD in a thickness direction (i.e., DR3) of the base layer BSL. For example, the contact portion CNT may be selectively disposed in an area where the opening OPN is not formed (e.g., FIG. 11).

Accordingly, the first power line VDD may cover the contact portion CNT, which is a path through which an anode signal is supplied. In this case, when a process for forming the second backplane layer BP2 is performed, a risk that generated light (for example, UV light) is applied to a path through which the anode signal is supplied may be prevented.

According to one or more embodiment, the anode electrode AE may be electrically connected to the first electrode ANO, and thus may supply the anode signal to the first electrode ANO. The cathode electrode CE may be electrically connected to the second electrode CAT, and thus may supply a cathode signal to the second electrode CAT (e.g., FIG. 12).

Next, referring to FIG. 12, the light-emitting-element layer EML disposed on the first backplane layer BP1 is described. FIG. 12 is a schematic cross-sectional view illustrating a display device according to one or more embodiments. FIG. 12 shows a cross-sectional structure of the display device 10 in the display area DA.

Referring to FIG. 12, the light-emitting-element layer EML may be disposed on the first backplane layer BP1.

The light-emitting-element layer EML may include first electrodes ANO, second electrodes CAT, and light emitting elements LE. Each of the first sub-pixel SPX1, the second sub-pixel SPX2, and the third sub-pixel SPX3 may include the light emitting element LE connected to the first electrode ANO and the second electrode CAT. According to one or more embodiments, the light emitting elements LE may include a first light emitting element LE1 configured to emit light of a first color and included in the first sub-pixel SPX1, a second light emitting element LE2 configured to emit light of a second color and included in the second sub-pixel SPX2, and a third light emitting element LE3 configured to emit light of a third color and included in the third sub-pixel SPX3. However, the present disclosure is not necessarily limited thereto. According to one or more embodiments, the first to third light emitting elements LE1, LE2, and LE3 may emit light of a same color, a color filter layer and/or a quantum-dot layer may be further disposed on the light-emitting-element layer EML, and thus a full-color display device 10 may be provided.

The first electrode ANO may be referred to as an anode electrode, and the second electrode CAT may be referred to as a cathode electrode.

The first electrodes ANO and the second electrodes CAT may be disposed on the first backplane layer BP1. Each of the first electrodes ANO may be electrically connected to the transistor TR of the first backplane layer BP1 via the anode electrode AE, a first bridge electrode BRD1, and a second bridge electrode BRD2. Accordingly, a pixel voltage or an anode voltage controlled by the transistor TR may be applied to the first electrode ANO.

Each of the second electrodes CAT may be electrically connected to the second power line VSS formed on the first backplane layer BP1 via the cathode electrode CE. Accordingly, one power voltage of the second power line VSS may be applied to the second electrodes CAT.

The first electrodes ANO and the second electrodes CAT may include a metal material having high reflectance such as a stack structure of aluminum and titanium (Ti/Al/Ti), a stack structure of aluminum and ITO (ITO/Al/ITO), an APC alloy, and/or a stack structure of an APC ally and ITO (ITO/APC/ITO). The APC alloy is an alloy of silver (Ag), palladium (Pd), and copper (Cu).

FIG. 12 illustrates that each of the light emitting elements LE is a flip chip type of micro LED (light-emitting diode) in which a first contact electrode CTE1 and a second contact electrode CTE2 are disposed to face the first electrode ANO and the second electrode CAT. However, a shape of the light emitting element LE is not necessarily limited thereto.

The light emitting element LE may include an inorganic material such as GaN. The length of the of the light emitting elements LE in each of the first direction DR1, the second direction DR2, and a third direction DR3 may be several to several hundreds of μm. For example, the length of the light emitting elements LE in each of the first direction DR1, the second direction DR2, and the third direction DR3 may be about 100 μm or less. However, the present disclosure is not limited thereto.

Each of the light emitting elements LE may be a light emitting structure including an n-type semiconductor NSEM, an active layer MQW, a p-type semiconductor PSEM, the first contact electrode CTE1, and the second contact electrode CTE2.

A portion of the n-type semiconductor NSEM may be disposed on the active layer MQW. A portion of the n-type semiconductor NSEM may be disposed on the second contact electrode CTE2. According to one or more embodiments, one surface of the n-type semiconductor NSEM may face a display surface. The n-type semiconductor NSEM may be formed of GaN doped with an n-type conductive dopant such as Si, Ge, and/or Sn. However, the present disclosure is not necessarily limited thereto.

The active layer MQW may be disposed on a portion of one surface of the n-type semiconductor NSEM. The active layer MQW may be interposed between the n-type semiconductor NSEM and the p-type semiconductor PSEM. The active layer MQW may include a material including a single or multi-quantum well structure. When the active layer MQW includes a material of the multi-quantum well structure, the active layer MQW may have a structure in which a plurality of well layers and barrier layers are alternately stacked. At this time, the well layer may be formed of InGaN, and the barrier layer may be formed of GaN or AlGaN, but are not limited thereto. Alternatively, the active layer MQW may have a structure in which a semiconductor material of a type having a high band gap energy and semiconductor materials having a low band gap energy are alternately stacked with each other, and may include Group III to V semiconductor materials that are different according to a wavelength band of emitted light.

The p-type semiconductor PSEM may be disposed on a surface of the active layer MQW. The p-type semiconductor PSEM may be formed of GaN doped with a p-type conductive dopant such as Mg, Zn, Ca, and/or Ba. However, the present disclosure is not necessarily limited thereto.

The first contact electrode CTE1 may be disposed on the p-type semiconductor PSEM, and the second contact electrode CTE2 may be disposed on another portion of a surface of the n-type semiconductor NSEM. The other portion of the surface of the n-type semiconductor NSEM on which the second contact electrode CTE2 is disposed may be disposed to be spaced from the portion of the surface of the n-type semiconductor NSEM on which the active layer MQW is disposed.

The first contact electrode CTE1 and the first electrode ANO may be adhered to each other through a conductive adhesive member such as an anisotropic conductive film (ACF) or an anisotropic conductive paste (ACP). Alternatively, the first contact electrode CTE1 and the first electrode ANO may be adhered to each other through a soldering process. However, the present disclosure is not necessarily limited thereto.

As described above, although the present disclosure has been described with reference to the one or more embodiments, those skilled in the art or those having a common knowledge in the art will understand that the present disclosure may be variously modified and changed without departing from the spirit and technical scope of the present disclosure described in the claims which will be described later.

Therefore, the technical scope of the present disclosure should not be limited to the contents described in the detailed description of the specification, but should be defined by the claims and their equivalents.

What is claimed is:

1. A display device comprising:
a base layer on a plane defined by a first direction and a second direction different from the first direction;
a front surface backplane layer on the base layer; and
a light emitting element on the front surface backplane layer,
wherein the front surface backplane layer comprises a first layer, a second layer on the first layer, and a third layer on the second layer,
wherein the first layer comprises a first power line, wherein at least a portion of the first power line extends in the first direction and at least another portion of the first power line extends in the second direction,
wherein the second layer comprises a pixel circuit configured to drive the light emitting element,
wherein the third layer comprises a second power line, wherein at least a portion of the second power line extends in the first direction and at least another portion of the second power line extends in the second direction, and
wherein the first power line and the second power line are physically separated by the second layer.

2. The display device according to claim 1, wherein the second layer comprises two or more insulating layers to electrically separate the first power line and the second power line.

3. The display device according to claim 1, wherein the pixel circuit comprises a transistor comprising a semiconductor layer, and
wherein the first power line overlaps the semiconductor layer in a thickness direction of the base layer.

4. The display device according to claim 3, wherein the first power line comprises a light blocking material.

5. The display device according to claim 3, wherein the second layer further comprises a power connection line electrically connected to the first power line,
wherein the transistor comprises a source electrode and a drain electrode, and
wherein the power connection line is on a same layer as the source electrode and the drain electrode.

6. The display device according to claim 1, further comprising:
pixels each including the light emitting element and being adjacent to each other,
wherein the pixel circuit is in a pixel circuit area between the adjacent pixels, and
wherein the pixel circuit area overlaps the first power line and the second power line in a thickness direction of the base layer.

7. The display device according to claim 6, wherein each of the pixels comprises a first sub-pixel, a second sub-pixel, and a third sub-pixel,
wherein the pixel circuit comprises a first pixel circuit configured to drive the first sub-pixel, a second pixel circuit configured to drive the second sub-pixel, and a third pixel circuit configured to drive the third sub-pixel,
wherein the first pixel circuit, the second pixel circuit, and the third pixel circuit are sequentially arranged along the first direction, and
wherein the adjacent pixels are spaced in the second direction.

8. The display device according to claim 1, wherein the third layer further comprises an anode electrode and a cathode electrode,
wherein the cathode electrode is electrically connected to the second power line, and
wherein the first power line overlaps the second power line, the anode electrode, and the cathode electrode in a thickness direction of the base layer.

9. The display device according to claim 8, wherein the second layer further comprises a bridge electrode,
wherein the bridge electrode is electrically connected to a transistor of the pixel circuit,
wherein the anode electrode is electrically connected to the bridge electrode through a contact portion, and
wherein the first power line and the contact portion overlap each other in a thickness direction of the base layer.

10. The display device according to claim 8, wherein the cathode electrode and the second power line are integrally formed.

11. The display device according to claim 8, wherein the anode electrode and the cathode electrode are spaced from each other in the first direction and extend in the second direction.

12. The display device according to claim 8, wherein the first power line includes an opening,
wherein the light emitting element is located in an emission area, and
wherein the opening and the emission area overlap each other in a plan view.

13. The display device according to claim 12, wherein the opening overlaps the anode electrode and the cathode electrode in a plan view.

14. The display device according to claim 1, wherein the light emitting element is a micro light-emitting diode.

15. The display device according to claim 1, further comprising:
a rear surface backplane layer on a rear surface of the base layer; and
a driving circuit unit configured to supply an electrical signal to the light emitting element,
wherein the rear surface backplane layer comprises a rear surface line electrically connected to the driving circuit unit.

16. A display device comprising:
a base layer on a plane defined by a first direction and a second direction different from the first direction;
a front surface backplane layer on a first surface of the base layer;
a rear surface backplane layer on a second surface of the base layer;
a light-emitting-element layer on the front surface backplane layer and comprising an anode electrode, a cathode electrode, and a light emitting element electrically connected to the anode electrode and the cathode electrode,
wherein the front surface backplane layer comprises a first layer, a second layer on the first layer, and a third layer on the second layer,
wherein the first layer comprises a first power line, at least a portion of the first power line extending in the first direction and at least another portion of the first power line extending in the second direction,
wherein the second layer comprises a transistor configured to drive the light emitting element and a bridge electrode electrically connecting the transistor and the anode electrode,
wherein the third layer comprises a second power line, at least a portion of the second power line extending in the first direction and at least another portion of the second power line extending in the second direction, and
wherein the bridge electrode and the first power line overlap each other in a thickness direction of the base layer.
